(19) United States
(12) Patent Application Publication
(10) Pub. No.: US 2012/0153507 A1
(43) Pub. Date: Jun. 21, 2012

(54) SEMICONDUCTOR DEVICE AND METHOD FOR MANUFACTURING THE SAME

(75) Inventors: Syota MIKI, Nagano (JP); Takaharu Yamano, Nagano (JP); Toshio Kobayashi, Nagano (JP)

(73) Assignee: Shinko Electric Industries Co., Ltd., Nagano-shi (JP)

(21) Appl. No.: 13/331,121

(22) Filed: Dec. 20, 2011

(30) Foreign Application Priority Data
Dec. 21, 2010 (JP) 2010-284110

(51) Int. Cl. H01L 23/48; H01L 21/56

(52) U.S. Cl. 257/782; 438/127; 257/E21.502; 257/E23.01

(57) ABSTRACT

A method include disposing a semiconductor chip having an electrode pad formed on a circuit forming surface on one surface of a support so that the electrode pad contacts with the one surface of the support, forming a first insulating layer on the one surface of the support so that the first insulating layer covers at least a side surface of the semiconductor chip, removing the support and forming an interconnection terminal on the electrode pad, forming a second insulating layer on the circuit forming surface of the semiconductor chip and the first insulating layer so that the second insulating layer covers the interconnection terminal, exposing an end portion of the interconnection terminal from a top surface of the second insulating layer, and forming a wiring pattern that is electrically connected to the end portion of the interconnection terminal, on the top surface of the second insulating layer.

### CROSS-REFERENCE TO RELATED APPLICATION(S)

The present application claims the benefit of priority of Japanese Patent Application No. 2010-284110, filed on Dec. 21, 2010. The disclosure of this application is incorporated herein by reference.

### BACKGROUND

1. Technical Field

The present disclosure relates to a semiconductor device having a semiconductor chip built therein and a method for manufacturing the same.

2. Related Art

Recently, semiconductor application products used for various mobile equipments such as digital cameras and cellular phones have become smaller, thinner, and lighter. Accordingly, semiconductor devices are required to be miniaturized and high density to be mounted in the mobile equipments, and a semiconductor device having a semiconductor chip built therein is suggested (see, for example, FIG. 1).

Hereinafter, a related-art semiconductor device and a method for manufacturing the same will be described with reference to the drawings. FIG. 1 is a cross-sectional view illustrating a related-art semiconductor device. Referring to FIG. 1, a related-art semiconductor device 100 includes a semiconductor chip 101, an interconnection terminal 102, a first insulating layer 103, a second insulating layer 104, a wiring pattern 105, a solder resist 106, and an external connection terminal 107.

The semiconductor chip 101 includes a thin film semiconductor substrate 109, a semiconductor integrated circuit 111, a plurality of electrode pads 112, and a protective film 113. The semiconductor substrate 109, for example, is formed by cutting a thin silicon wafer into pieces.

The semiconductor integrated circuit 111 is formed on a surface of the semiconductor substrate 109. The semiconductor integrated circuit 111 is configured by a diffusion layer, an insulating layer, vias, and wiring lines (not shown). The plurality of electrode pads 112 are formed on the semiconductor integrated circuit 111. The plurality of electrode pads 112 are electrically connected with the wiring lines (not shown) provided in the semiconductor integrated circuit 111. The protective film 113 is formed on the semiconductor integrated circuit 111. The protective film 113 is a film to protect the semiconductor integrated circuit 111.

The interconnection terminal 102 is formed on the electrode pad 112. A top surface (a surface contacting with the wiring pattern 105) of the interconnection terminal 102 is exposed through the first insulating layer 103, and electrically connected with the wiring pattern 105. The first insulating layer 103 is provided so as to cover the semiconductor chip 101 on which the interconnection terminal 102 is formed. The first insulating layer 103 may be formed of an adhesive sheet type insulating resin (for example, NCF (non-conductive film)).

The second insulating layer 104 is provided so as to cover side and rear surfaces of the semiconductor chip 101, and side surfaces of the first insulating layer 103. The second insulating layer 104 may be formed of a molding resin. There is a step part of several μm at the interface between the first insulating layer 103 and the second insulating layer 104 (a portion where the first insulating layer 103 and the second insulating layer 104 contact with the wiring pattern 105, which is denoted by a dashed line A in FIG. 1).

The wiring pattern 105 is provided on the first insulating layer 103 and the second insulating layer 104. The wiring pattern 105 is electrically connected with the interconnection terminal 102 and further electrically connected with the electrode pad 112 through the interconnection terminal 102. The solder resist 106 is provided on the first insulating layer 103 and the second insulating layer 104 so as to cover the wiring pattern 105. The solder resist 106 includes opening 106x and a part of the wiring pattern 105 is exposed through the opening 106x.

The external connection terminal 107 is provided on the wiring pattern 105 which is exposed through the opening 106x. The external connection terminal 107 is electrically connected with the wiring pattern 105.

FIGS. 2 to 4 are views illustrating a process of manufacturing a related-art semiconductor device. In FIGS. 2 to 4, the same components as the related-art semiconductor device 100 shown in FIG. 1 are denoted by the same reference numerals, and the description thereof will be omitted.

First, in the process shown in FIG. 2, using a known method, a semiconductor chip 101 including a semiconductor integrated circuit 111, a plurality of electrode pads 112, and a protective film 113, is formed on a surface of a semiconductor substrate 109. An interconnection terminals 102 are formed on the electrode pads 112, and a first insulating layer 103 formed of a resin is further formed so as to cover the interconnection terminal 102 and the protective film 113, so that a top surface of the interconnection terminal 102 is exposed from the first insulating layer 103. The first insulating layer 103 may be formed of an adhesive sheet type insulating resin (for example, NCF (non-conductive film)).

Next, in the process shown in FIG. 3, a support 200 is provided and the structure shown in FIG. 2 is disposed on one surface of the support 200 so that the first insulating layer 103 is contact with the one surface of the support 200.

Next, in the process shown in FIG. 4, a molding resin is applied on the one surface of the support 200 so as to cover the structure shown in FIG. 2, and then heated and cured to form a second insulating layer 104.

Thereafter, the support 200 is removed and a wiring pattern 105, a solder resist 106 and an external connection terminal 107 are formed on a portion where the interconnection terminal 102 is exposed, thereby forming the semiconductor device 100 shown in FIG. 1.

[Patent Document 1] Japanese Patent Application Laid-Open No. 2010-109181 A

[Patent Document 2] Japanese Patent Application Laid-Open No. 2004-327724 A

[Patent Document 3] Japanese Patent Application Laid-Open No. 2008-311592 A

However, a step part, which is formed at the interface between the first insulating layer 103 and the second insulating layer 104, denoted by the dashed line A in FIG. 1, is caused by the difference in thermal shrinkage rates of the first insulating layer 103 and the second insulating layer 104. That is, since different materials are used for the first insulating layer 103 and the second insulating layer 104, when the first insulating layer 103 and the second insulating layer 104 are heated and then returned to the room temperature in the process as shown in FIG. 4, the step part is generated at the interface of the first insulating layer 103 and the second insulating layer 104 due to the difference in the thermal shrinkage rates thoseof.

When the step part is generated at the interface of the first insulating layer 103 and the second insulating layer 104, cracks or disconnection may occur in the wiring pattern 105 that extends from a top surface (a surface contacting with the wiring pattern 105) of the first insulating layer 103 to a top surface (a surface contacting with the wiring pattern 105) of the second insulating layer 104. Even though there is no inherent disconnection in the wiring pattern 105 at the time of manufacturing the semiconductor device 100, if the wiring pattern has a small crack, disconnection may be subsequently generated in the wiring pattern 105 due to the thermal stress caused by the change in the used environmental temperature of the semiconductor device 100.

### SUMMARY

Exemplary embodiments of the invention provide a semiconductor device and a method for manufacturing the same which is capable of preventing the crack or the disconnection from being generated in the wiring pattern.

A semiconductor device according to an exemplary embodiment includes:

a semiconductor chip having an electrode pad formed on a circuit forming surface;

an interconnection terminal formed on the electrode pad;

a first insulating layer formed so as to cover a side surface and a rear surface of the semiconductor chip;

a second insulating layer formed on the circuit forming surface of the semiconductor chip and the first insulating layer so as to expose an end portion of the interconnection terminal and cover the other portions except the end portion, the second insulating layer having a first surface facing the circuit forming surface of the semiconductor chip and the first insulating layer and a second surface opposite to the first surface; and

a wiring pattern formed on the second surface of the second insulating layer and electrically connected with the end portion of the interconnection terminal.

A method for manufacturing a semiconductor device according to an exemplary embodiment includes:

a first process of disposing a semiconductor chip having an electrode pad formed on a circuit forming surface on one surface of a support so that the electrode pad contacts with the one surface of the support;

a second process of forming a first insulating layer on the one surface of the support so that the first insulating layer covers at least a side surface of the semiconductor chip and has a first surface facing the one surface of the support;

a third process of removing the support and forming an interconnection terminal on the electrode pad;

a fourth process of forming a second insulating layer on the circuit forming surface of the semiconductor chip and the first insulating layer so that the second insulating layer covers the interconnection terminal and has a first surface facing the circuit forming surface of the semiconductor chip and the first insulating layer and a second surface opposite to the first surface;

a fifth process of exposing an end portion of the interconnection terminal from the second surface of the second insulating layer; and

a sixth process of forming a wiring pattern that is electrically connected to the end portion of the interconnection terminal, on the second surface of the second insulating layer.

According to the embodiments of the present invention, it is possible to provide a semiconductor device and a method for manufacturing the same which is capable of preventing the crack or the disconnection from being generated in the wiring pattern.

### BRIEF DESCRIPTION OF THE DRAWINGS

FIG. 1 is a cross-sectional view illustrating a related-art semiconductor device.

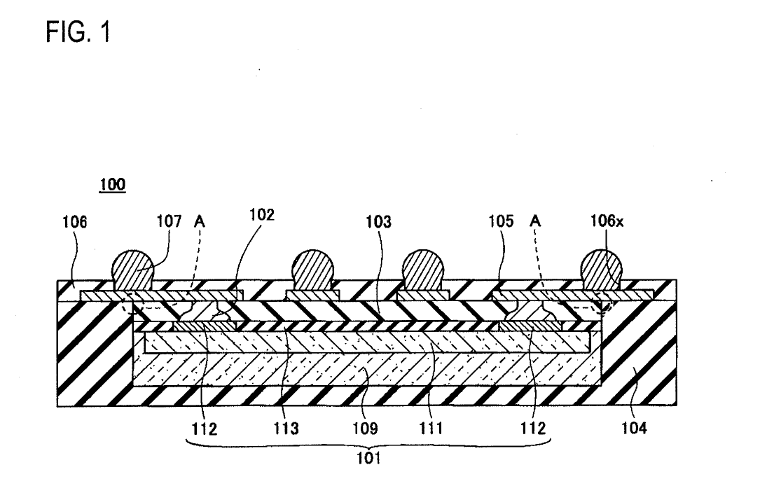

FIG. 2 is a (first) view illustrating a process of manufacturing the related-art semiconductor device.

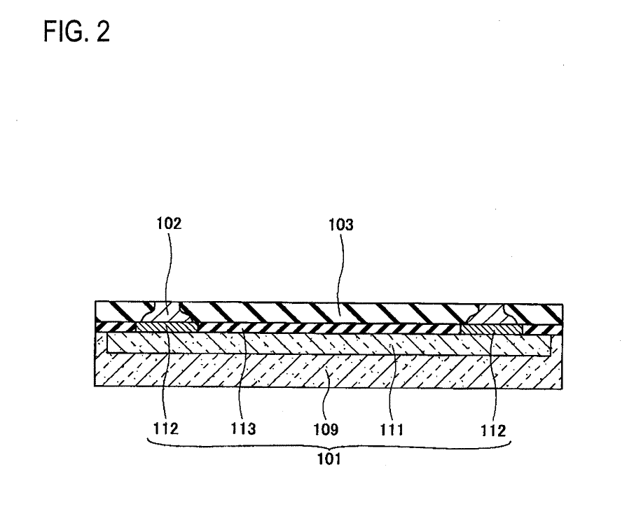

FIG. 3 is a (second) view illustrating a process of manufacturing the related-art semiconductor device.

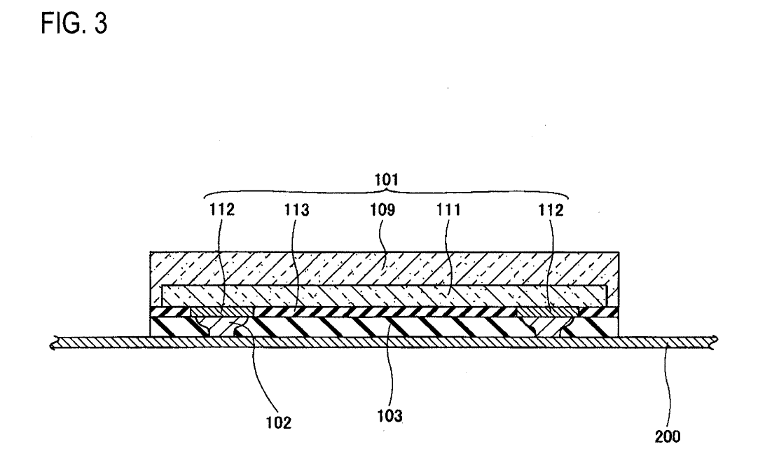

FIG. 4 is a (third) view illustrating a process of manufacturing the related-art semiconductor device.

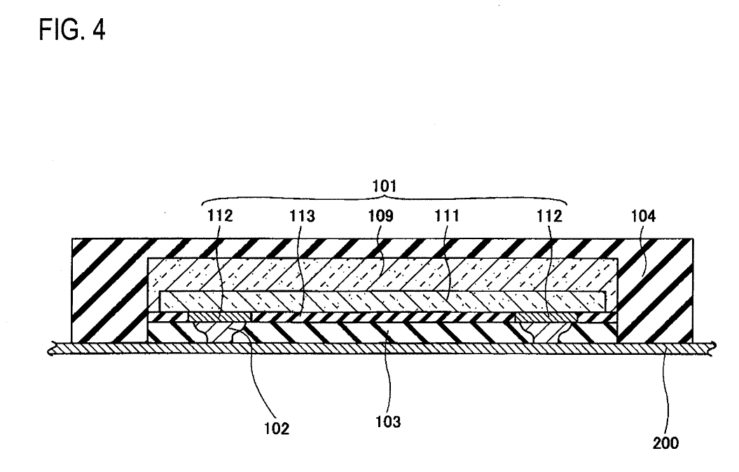

FIG. 5 is a cross-sectional view illustrating a semiconductor device according to an exemplary embodiment.

FIG. 6 is a (first) view illustrating the process of manufacturing the semiconductor device according to the exemplary embodiment.

FIG. 7 is a (second) view illustrating the process of manufacturing the semiconductor device according to the exemplary embodiment.

FIG. 8 is a (third) view illustrating the process of manufacturing the semiconductor device according to the exemplary embodiment.

FIG. 9 is a (fourth) view illustrating the process of manufacturing the semiconductor device according to the exemplary embodiment.

FIG. 10 is a (fifth) view illustrating the process of manufacturing the semiconductor device according to the exemplary embodiment.

FIG. 11 is a (sixth) view illustrating the process of manufacturing the semiconductor device according to the exemplary embodiment.

FIG. 12 is a (seventh) view illustrating the process of manufacturing the semiconductor device according to the exemplary embodiment.

FIG. 13 is a (eighth) view illustrating the process of manufacturing the semiconductor device according to the exemplary embodiment.

FIG. 14 is a (ninth) view illustrating the process of manufacturing the semiconductor device according to the exemplary embodiment.

FIG. 15 is a (tenth) view illustrating the process of manufacturing the semiconductor device according to the exemplary embodiment.

FIG. 16 is a (eleventh) view illustrating the process of manufacturing the semiconductor device according to the exemplary an embodiment.

### DETAILED DESCRIPTION

Hereinafter, embodiments of the present invention will be described with reference to the accompanying drawings. In the drawings, the same components may be denoted by the same reference numerals, and the description thoseof will be omitted.

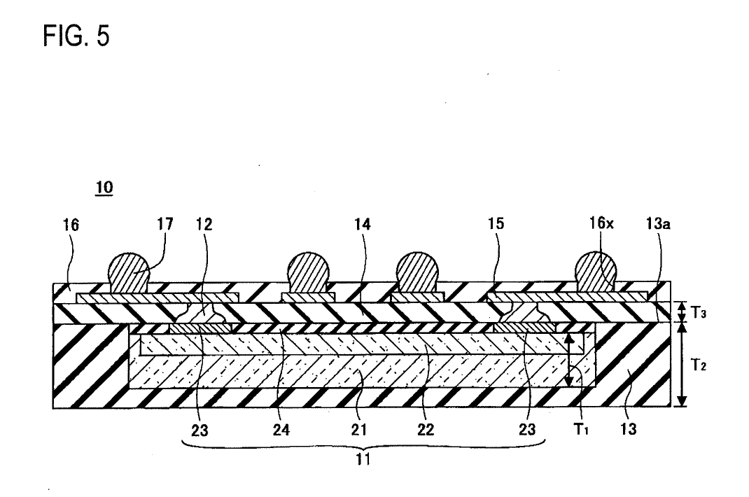

FIG. 5 is a cross-sectional view illustrating a semiconductor device according to an exemplary embodiment of the present disclosure. Referring to FIG. 5, a semiconductor device 10 includes a semiconductor chip 11, an interconnection terminal 12, a first insulating layer 13, a second insulating layer 14, a wiring pattern 15, a solder resist 16, and an external connection terminal 17. The semiconductor device 10 is a rectangular shape and may have a width of 7 mm to 15 mm, a length of 7 mm to 15 mm, and a thickness of 0.6 mm.

The semiconductor chip 11 includes a semiconductor substrate 21, a semiconductor integrated circuit 22, a plurality of electrode pads 23, and a protective film 24. The semiconductor chip 11 is a rectangular shape and may have a width of 5 mm to 10 mm, a length of 5 mm to 10 mm, and a thickness of 0.4 mm to 0.5 mm.

The semiconductor substrate 21 is a substrate for forming the semiconductor integrated circuit 22. The semiconductor substrate 21 is thinned, and the thickness T₁ thereof (including the thickness of the semiconductor integrated circuit 22) may be approximately 300 μm to 400 μm. For example, the semiconductor substrate 21 is formed by cutting a thin silicon wafer into pieces.

The semiconductor integrated circuit 22 is formed on a top surface of the semiconductor substrate 21. The semiconductor integrated circuit 22 is configured by a diffusion layer (not shown) formed on the semiconductor substrate 21, an insulating layer (not shown) stacked on the semiconductor substrate 21, and vias (not shown) and wiring lines (not shown) formed in the stacked insulating layer. Hereinafter, a surface of the semiconductor chip 11, on which the semiconductor integrated circuit 22 is formed, may be referred to as a circuit forming surface. A surface of the semiconductor chip 11 that is disposed opposite side to the circuit forming surface and substantially parallel to the circuit forming surface may be referred to as a rear surface. A surface of the semiconductor chip 11 that is substantially perpendicular to the circuit forming surface and the rear surface may be referred to as a side surface.

The plurality of electrode pads 23 are formed on the semiconductor integrated circuit 22. The plurality of electrode pads 23 are electrically connected with the wiring lines (not shown) provided in the semiconductor integrated circuit 22. An example of a material for the electrode pad 23 may include aluminum (Al). Another example of the material for the electrode pad 23 may include an Al layer formed on a Cu layer. Alternatively, the material for the electrode pad 23 may include a Si layer formed on a Cu layer in which an Al layer is further formed thereon. The pitch between the electrode pads 23 may be, for example, 60 μm to 100 μm.

The protective film 24 is provided on the top surface of the semiconductor substrate 21 and the semiconductor integrated circuit 22. The protective film 24 is a film to protect the semiconductor integrated circuit 22, and also referred to as a passivation film. As the protective film 24, for example, a SiN film or a PSG film may be used. A polyimide layer may be stacked on a layer formed of a SiN film or a PSG film.

The interconnection terminal 12 is provided on the electrode pads 23 of the semiconductor chip 11, and electrically connects the semiconductor integrated circuit 22 of the semiconductor chip 11 with the wiring pattern 15. The height of the interconnection terminal 12 may be approximately 20 μm to 60 μm. As the interconnection terminal 12, an Au bump, a Cu bump, an Au plated film, or a metal film consisting of a Ni film formed by a non-electrolytic plating method and an Au film covering the Ni film may be used.

The first insulating layer 13 is provided so as to cover the side surfaces and the rear surface of the semiconductor chip 11. The first insulating layer 13 is a part of a base substance at the time of forming the second insulating layer 14. One surface 13a of the first insulating layer 13 is substantially coplanar to a top surface (a surface contacting with the interconnection terminal 12) of the electrode pad 23 and a top surface (a surface contacting with the second insulating layer 14) of the protective film 24. The thickness T₂ of the first insulating layer 13 may be approximately 400 μm to 500 μm.

Examples of the material for the first insulating layer 13 may include an adhesive B-stage status (semi-cured status) sheet type insulating resin (for example, NCF (Non Conductive Film)), a paste type insulating resin (for example, NCP (Non Conductive Paste)), an adhesive sheet type anisotropic conductive resin (for example, ACF (Anisotropic Conductive Film)), a paste type anisotropic conductive resin (for example, ACP (Anisotropic Conductive Paste)), a build-up resin (an epoxy resin having a filler or an epoxy resin without a filler), a liquid crystal polymer, a molding resin, etc. The ACP and the ACF are formed such that a small diameter spherical resin coated by Ni/Au is dispersed in an epoxy resin based insulating resin. Therefore, the ACP and the ACF has conductivity in a vertical direction and has insulation properties in a horizontal direction. The molding resin is preferable for the material for the first insulating layer 13 because thickness of the molding resin can be adjusted with high accuracy.

The second insulating layer 14 is provided on the surface 13a of the first insulating layer 13, the top surface (the surface contacting with the interconnection terminal 12) of the electrode pad 23, and the top surface (the surface contacting with the second insulating layer 14) of the protective film 24 so as to cover the interconnection terminal 12. In this case, the end portion of the interconnection terminal 12 is exposed from the top surface of the second insulating layer 14. A top surface (a surface contacting with the wiring pattern 15) of the second insulating layer 14 is substantially coplanar to the end portion (flat surface) of the interconnection terminal 12. The second insulating layer 14 seals and protects the circuit forming surface of the semiconductor chip 11 and becomes a base substance when forming the wiring pattern 15. The thickness T₃ of the second insulating layer 14 is almost the same as the height of the interconnection terminal 12, and for example, may be approximately 20 μm to 60 μm.

As the materials for the second insulating layer 14, the same materials to the first insulating layer 13 may be used. However, it is preferable that the same material is used for both the first insulating layer 13 and the second insulating layer 14. Because the physical properties (thermal expansion coefficients) of the first insulating layer 13 and the second insulating layer 14 become equal to each other, the thermal stress generated in the first insulating layer 13 or the second insulating layer 14 can be reduced, which can prevent the first insulating layer 13 and the second insulating layer 14 from being separated from the interface or the entire semiconductor device 10 from being bent.

The wiring pattern 15 is provided on the top surface of the second insulating layer 14 and electrically connected with the end portion of the interconnection terminal 12. That is, the wiring pattern 15 is electrically connected with the semiconductor integrated circuit 11 through the interconnection terminal 12. The thickness of the wiring pattern 15 is, for example, 5 μm to 20 μm. As a material for the wiring pattern 15, Cu may be used. However, the wiring pattern 15 may be formed with a stacked structure of a Ti layer and a Cu layer or a stacked structure of a Cr layer and a Cu layer. The wiring pattern 15 may be called a, rewiring, and be provided to make the position of the electrode pad 23 and the position of the external connection terminal 17 to be different from each other (in order to dispose a terminal in a fan-out position or an arbitrary position, or to change the pitch).

The solder resist 16 is provided on the top surface of the second insulating layer 14 so as to cover the wiring pattern 15. The solder resist 16 has an opening 16x, and a part of the wiring pattern 15 is exposed in the opening 16x. As a material for the solder resist 16, an epoxy-based resin may be used.

The external connection terminal 17 is provided on the wiring pattern 15 that is exposed in the opening 16x. According to the embodiment, since the semiconductor device 10 has a fan-out structure, the external connection terminal 17 is formed even at a portion where the external connection terminal 17 overlaps with the first insulating layer 13 when viewed from above. By increasing the area of the first insulating layer 13 that is formed at the outside of the circuit forming surface of the semiconductor device 10, it is possible to form more external connection terminals 17.

The external connection terminal 17 is electrically connected with a pad installed on a substrate for mounting (not shown) such as a mother board. As the external connection terminal 17, for example, a solder bump may be used. When the solder bump is used as the external connection terminal 17, the material for the external connection terminal 17 may include an alloy containing Pb, an alloy of Sn and Cu, an alloy of Sn and Ag, or an alloy of Sn, Ag, and Cu. A solder ball (Sn-3.5Ag) having a resin (for example, divinylbenzene) as a core may be used.

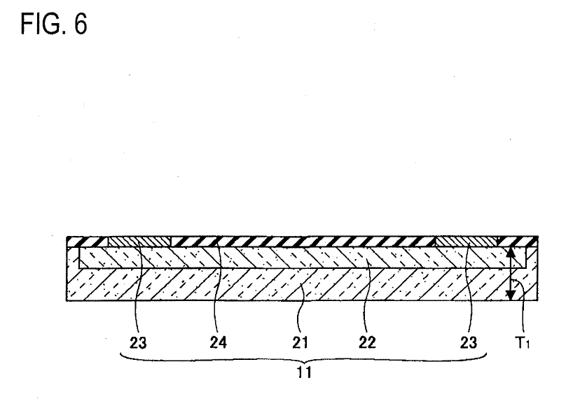

FIGS. 6 to 16 are views illustrating a process of manufacturing the semiconductor device according to the exemplary embodiment. In the process shown in FIG. 6, a Si wafer on which a plurality of semiconductor chips 11 are formed is prepared. If needed, the rear surface of the semiconductor substrate 21 that constitutes the semiconductor chip 11 is ground to be thinned and further the thinned Si wafer is cut into pieces to manufacture a plurality of semiconductor chips 11. The thickness T₁ (including a thickness of the semiconductor integrated circuit 22) of the semiconductor substrate 21 may be approximately 300 μm to 400 μm.

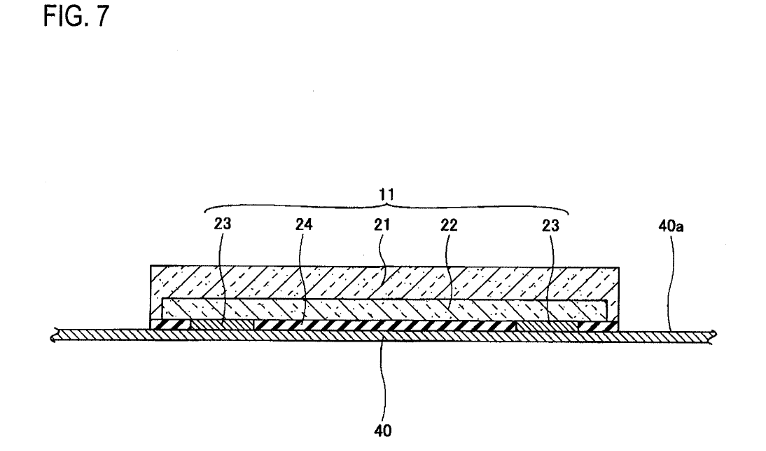

Next, in the process shown in FIG. 7, a support 40 is prepared. The plurality of semiconductor chips 11 are disposed on one surface 40a of the support 40 at a predetermined interval so that the electrode pad 23 and the protective film 24 contact with the one surface 40a of the support 40. The one surface 40a of the support 40 has adhesion property and the disposed semiconductor chips 11 are fixed thereto. If the one surface 40a of the support 40 does not have adhesion property, the semiconductor chips 11 are fixed thereto using for example, an adhesive tape. As for the support 40, a PET film, a polyimide film, a metal plate, or a glass plate may be used. The planar shape of the support 40 may be any shape such as a rectangular shape and a circular shape.

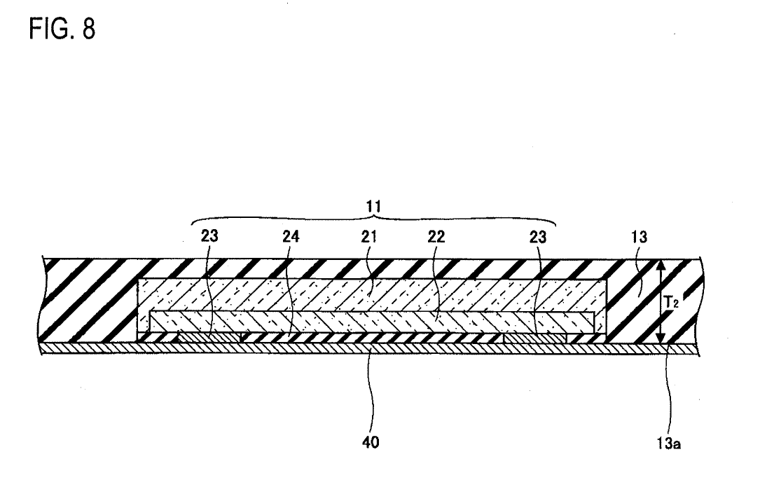

Next, in the process shown in FIG. 8, the first insulating layer 13 is formed on the one surface 40a of the support 40 so as to cover the side surfaces and the rear surfaces of the plurality of semiconductor chips 11. The thickness T₂ of the first insulating layer 13 may be 400 μm to 500 μm. The material for the first insulating layer 13 is as described above. The first insulating layer 13 may be formed such that an adhesive B-stage status (semi-cured status) sheet type insulating resin (for example, NCF) is laminated on the one surface 40a of the support 40, and the laminated sheet type insulating resin is pressed, and then the pressed insulating resin is cured by a heat treatment at a predetermined temperature. The first insulating layer 13 may be formed such that the paste type insulating resin (for example, NCP) is applied on the one surface 40a of the support 40 and then the applied paste type insulating resin is cured by a heat treatment at a predetermined temperature.

In the process shown in FIG. 8, the first insulating layer 13 may be formed so as to cover at least the side surface of the semiconductor chip 11 which is disposed on the one surface 40a of the support 40, but the first insulating layer 13 does not need to be formed to cover the rear surface of the semiconductor chip 11. If the rear surface of the semiconductor chip 11 is exposed, the heat dissipating performance of the semiconductor chip 11 can be improved.

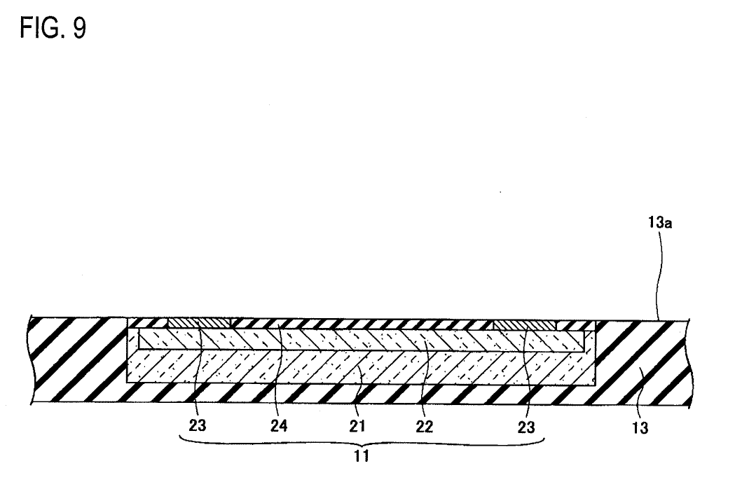

Next, in the process shown in FIG. 9, the support 40 shown in FIG. 8 is removed. For example, the support 40 may be mechanically peeled off. If the support 40 is a metal plate, the support 40 may be removed by etching. After removing the support 40, a plasma cleaning processing is performed in order to ensure the surface reformation of the first insulating layer 13 (to improve the wettability) and the surface clean-up of the electrode pad 23. An example of the plasma cleaning processing may include O₂ plasma ashing. In O₂ plasma ashing, under the vacuum atmosphere, a target material is oxidized by oxygen radical in which oxygen gas is plasma-activated and oxygen ion and then removed by gaseous reaction product such as CO or CO₂.

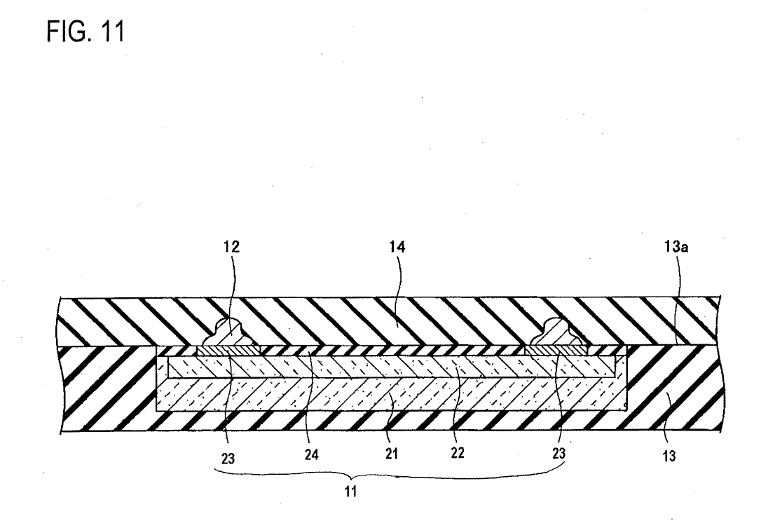

Various inert gases may be added to the supplied oxygen gas if necessary. Examples of the inert gas may include argon-based gas, hydrogen-based gas, nitrogen-based gas, or CF-based gas such as CF₄ or C₂F₆. A top surface (a surface contacting with the second insulating layer 14) of the first insulating layer 13 is roughened by the plasma cleaning processing and fine irregularities are formed thereon. By roughening the top surface of the first insulating layer 13, in the step shown in FIG. 11 which will be described below, an adhesion property of the top surface of the first insulating layer 13 and the bottom surface of the second insulating layer 14 can be improved. FIG. 9 shows the structure as up and down reverse manner to the structure shown in FIG. 8.

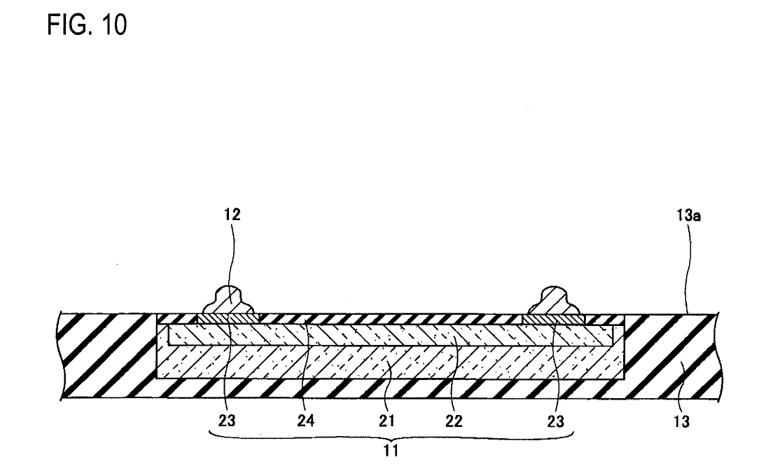

Next, in the process shown in FIG. 10, interconnection terminals 12 are formed on the individual electrode pads 23 provided on the individual semiconductor chips 11. As the interconnection terminal 12, an Au bump, a Cu bump, an Au plated film, or a metal film consisting of a Ni film formed by a non-electrolytic plating method or an Al zincate method and an Au film stacked on the Ni film may be used. The Au bump or the Cu bump may be formed by a bonding wire using a wire bonding apparatus or may be formed by a plating method. The respective interconnection terminals 12 formed in the process shown in FIG. 10 have height difference.

Next, in the process shown in FIG. 11, a second insulating layer 14 is formed on the semiconductor chip 11 (on a part of the electrode pad 23 and the protective film 24) and on the one surface 13a of the first insulating layer 13 so as to cover the interconnection terminal 12. The material for the second insulating layer 14 is as described above. However, for the above-mentioned reason, it is preferable that the first insulating layer 13 and the second insulating layer 14 use the same material. The second insulating layer 14 may be formed by the same method as the first insulating layer 13.

The top surface of the first insulating layer 13 is roughened by the process shown in FIG. 9, so that fine irregularities are formed thereon. Therefore, the second insulating layer 14 is stuck in the minute irregularities formed on the top surface of the first insulating layer 13, so called, the anchor effect occurs, which improves the adhesion property between the first insulating layer 13 and the second insulating layer 14.

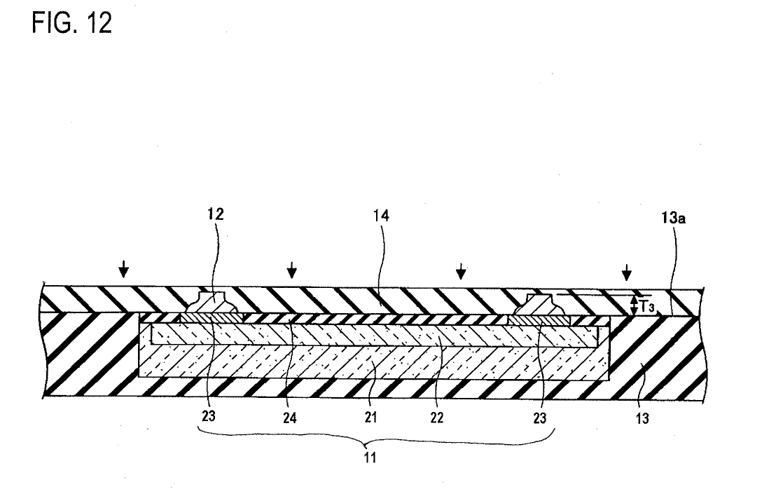

Next, in the process shown in FIG. 12, under the status where the structure shown in FIG. 11 is heated, the second insulating layer 14 is pressed from the top surface of the second insulating layer 14 (pressed in the direction indicated by an arrow of FIG. 12). Accordingly, the top surface of the second insulating layer 14 and the end portion of the interconnection terminal 12 become a flat surface, and the end portion of the interconnection terminal 12 is exposed from the top surface of the second insulating layer 14. As described above, in this process, the planarizing processing for both the top surface of the second insulating layer 14 and the end portion of the interconnection terminal 12 can be simultaneously performed. However, in this status, onto the end portion of the interconnection terminal 12 that is exposed from the top surface of the second insulating layer 14, some of the materials forming the second insulating layer 14 are adhered. Continuously, the second insulating layer 14 is cured by heating the second insulating layer 14 at a higher temperature (the curing temperature of the second insulating layer 14) than the temperature when the second insulating layer 14 is pressed. The height T₃ (≈thickness of the second insulating layer 14) of the interconnection terminal 12 after pressing may be 20 μm to 60 μm.

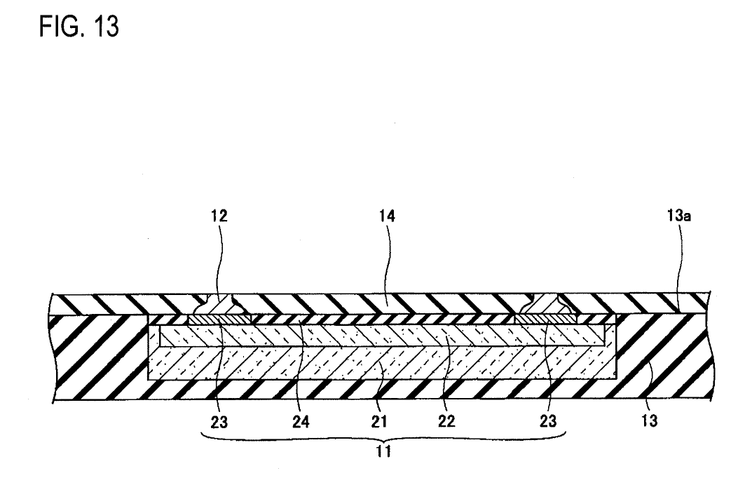

Next, in the process shown in FIG. 13, an ashing processing is performed on the top surface of the second insulating layer 14 to remove the material forming the second insulating layer 14 that is adhered onto the end portion of the interconnection terminal 12. The end portion of the interconnection terminal 12 is totally exposed from the second insulating layer 14 and the top surface of the second insulating layer 14 is roughened. Accordingly, the top surface of the second insulating layer 14 and the end portion (flat surface) of the interconnection terminal 12 are substantially coplanar to each other. An example of the ashing processing may include O₂ plasma ashing as used in the process shown in FIG. 9.

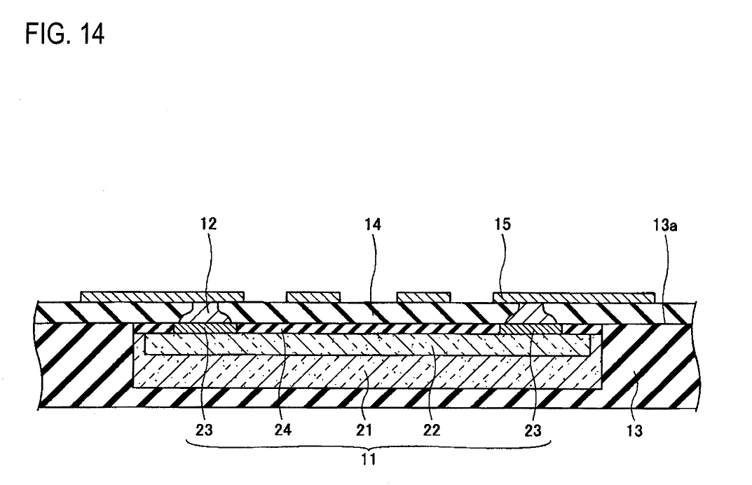

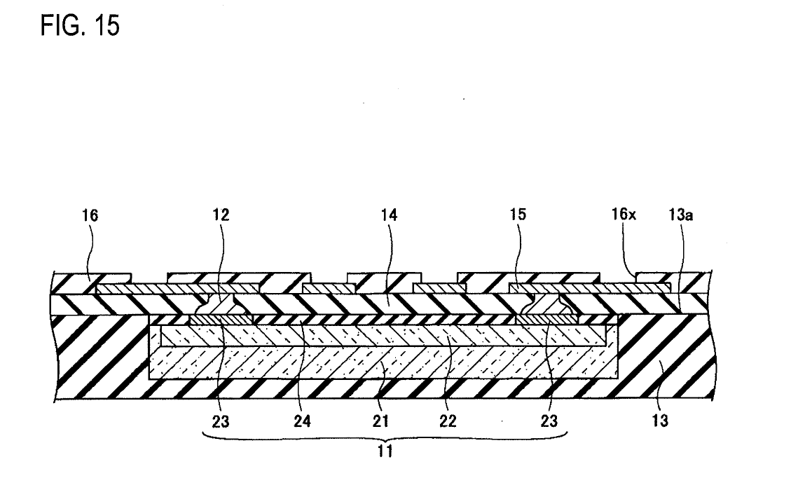

The surface which is subject to the ashing processing is roughened, so that fine irregularities are formed thereon. By roughening the top surface of the second insulating layer 14 by the process shown in FIG. 13, the adhesion property of the top surface of the second insulating layer 14 and the wiring pattern 15 which will be formed in the process shown in FIG. 14 to be described below can be improved. Further, the adhesion property of the top surface of the second insulating layer 14 and the solder resist 16 formed in the process shown in FIG. 15 which will be described below can be improved.

Next, in the process shown in FIG. 14, on the top surface of the second insulating layer 14, the wiring pattern 15 that is electrically connected to the end portion of the interconnection terminal 12 is formed. The wiring pattern 15 is electrically connected to the semiconductor integrated circuit 22 through the interconnection terminal 12. The thickness of the wiring pattern 15 may be, for example, 5 μm to 20 μm. As the material for the wiring pattern 15, Cu may be used. The wiring pattern 15 may be formed by using various wiring forming methods such as a semi additive process or a subtractive process. For example, a method of forming the wiring pattern 15 using the semi additive process will be described below.

First, a seed layer (not shown), on which a Ti layer and a Cu layer are stacked in this order, is formed on the top surface of the second insulating layer 14 by a sputtering method. A resist layer (not shown) is further formed on the seed layer, and the formed resist layer (not shown) is exposed and developed to form an opening corresponding to the wiring pattern 15. A Cu layer (not shown) is formed in the opening of the resist layer by an electrolyte plating method that uses the seed layer as a power feeding layer. Continuously, after removing the resist layer, using the Cu layer as a mask, a part of the seed layer that is not covered by the Cu layer is removed by etching. Accordingly, on the top surface of the second insulating layer 14, the wiring pattern 15 on which the Ti layer and the Cu layer are stacked is formed.

By the process shown in FIG. 13 described above, the top surface of the second insulating layer 14 is roughened, so that minute irregularities are formed thereon. Therefore, the wiring pattern 15 is stuck in the minute irregularities formed on the top surface of the second insulating layer 14, so called, the anchor effect occurs, which improves the adhesion property between the second insulating layer 14 and the wiring pattern 15.

Next, in the process shown in FIG. 15, a resist is applied so as to cover the wiring pattern 15 and the second insulating layer 14, and then the resist is exposed and developed by a photolithographic method to form the solder resist 16 having openings 16x. An example of the material for the solder resist 16 may include a photosensitive epoxy-based resin.

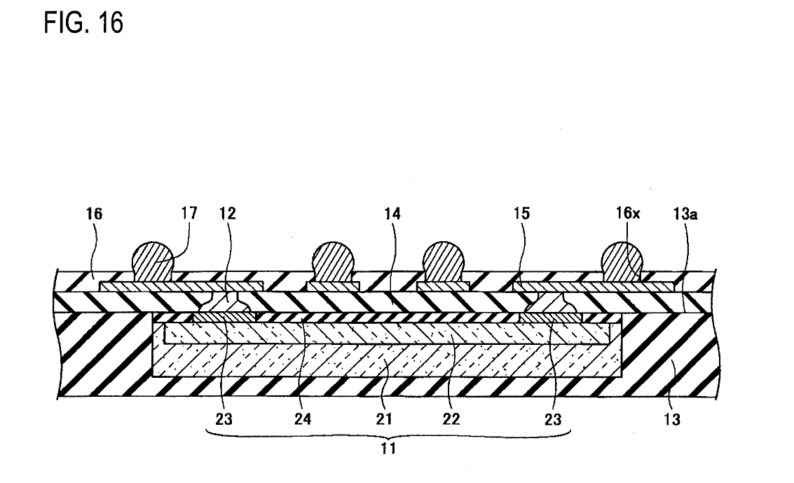

Next, in the process shown in FIG. 16, the external connection terminal 17 is formed on the portion of the wiring pattern 15 that is exposed through the opening 16x. A solder bump may be used as the external connection terminal 17. Examples of the material when the external connection terminal 17 is the solder bump may include an alloy containing Pb, an alloy of Sn and Cu, an alloy of Sn and Ag, or an alloy of Sn, Ag, and Cu. A solder ball (Sn-3.5 Ag) having a resin (for example, divinylbenzene) as a core may be used.

By making pieces by cutting the structure shown in FIG. 16 at a predetermined position, a plurality of semiconductor devices 10 (see FIG. 5) are manufactured. The cutting of the structure shown in FIG. 16 may be performed by dicing using a dicing blade.

As described above, according to the embodiment of the present invention, the second insulating layer 14 is formed so as to cover the interconnection terminal 12, the protective film 24 and the one surface 13a of the first insulating layer 13, and the wiring pattern 15 is formed on the top surface of the second insulating layer 14. That is, the wiring pattern 15 is formed only on the flat top surface of the second insulating layer 14, not on the step part of the interface of two insulating layers as in the semiconductor device according to the related art. Therefore, it is possible to prevent the crack or disconnection in the wiring pattern 15. When the semiconductor device 10 is originally manufactured without cracks in the wiring pattern 15, it is possible to reduce the possibility of disconnection even when the thermal stress caused by the change in the usage environmental temperature of the semiconductor device 10 is continuously applied.

According to the embodiment of the present invention, the area of the one surface 13a of the first insulating layer 13 is designed to be large, which makes it possible to easily arrange the plurality of external connection terminals having a fan-out structure.

While the embodiments has been described in detail, the present invention is not limited to the embodiments and it will be apparent to one skilled in the art that various changes and modifications can be made therein without departing from the spirit and the scope of the claims.

For example, in the process shown in FIG. 15 or FIG. 16, a rear surface of the first insulating layer 13 may be ground to expose the rear surface of the semiconductor chip 11, thereby improving the heat dissipating performance of the semiconductor chip 11. Further, a heat dissipating component such as a heat spreader may be attached onto the rear surface of the semiconductor chip 11, thereby further improving the heat dissipating performance of the semiconductor chip 11. In addition, when the rear surface of the first insulating layer 13 is ground, the rear surface of the semiconductor chip 11 may be also ground and the semiconductor chip 11 can be thinner.

While certain embodiments have been described, these embodiments have been presented by way of example only, and are not intended to limit the scope of the invention. Indeed, the novel device and method described herein may be embodied in a variety of other forms; furthermore, various omissions, substitutions and changes in the form of the device and method, described herein may be made without departing from the sprit of the invention. The accompanying claims and their equivalents are intended to cover such forms or modifications as would fall within the scope and sprit of the invention

What is claimed is:

1. A method for manufacturing a semiconductor device, comprising:
a first process of disposing a semiconductor chip having an electrode pad formed on a circuit forming surface on one surface of a support so that the electrode pad contacts with the one surface of the support;
a second process of forming a first insulating layer on the one surface of the support so that the first insulating layer covers at least a side surface of the semiconductor chip, and has a first surface facing the one surface of the support;
a third process of removing the support and forming an interconnection terminal on the electrode pad;
a fourth process of forming a second insulating layer on the circuit forming surface of the semiconductor chip and the first insulating layer so that the second insulating layer covers the interconnection terminal and has a first surface facing the circuit forming surface of the semiconductor chip and the first insulating layer, and a second surface opposite to the first surface;
a fifth process of exposing an end portion of the interconnection terminal from the second surface of the second insulating layer; and
a sixth process of forming a wiring pattern that is electrically connected to the end portion of the interconnection terminal, on the second surface of the second insulating layer.

2. The method of claim 1, wherein, in the second process, the first insulating layer is formed on the one surface of the support so as to cover the side surface and a rear surface of the semiconductor chip.

3. The method of claim 1, further comprising:
a seventh process of roughening the first surface of the first insulating layer after removing the support and before forming the interconnection terminal, in the third process.

4. The method of claim 1, further comprising:
an eighth process of roughening the second surface of the second insulating layer between the fifth process and the sixth process.

5. The method of claim 1, wherein, in the fifth process, the end portion of the interconnection terminal is exposed from the second surface of the second insulating layer by pressing the second insulating layer from the second surface thereof so that the second surface of the second insulating layer is planarized and the end portion of the interconnection terminal is planarized.

6. The method of claim 1, wherein the first insulating layer and the second insulating layer are formed of the same material.

7. A semiconductor device, comprising:
a semiconductor chip having an electrode pad formed on a circuit forming surface;
an interconnection terminal formed on the electrode pad;
a first insulating layer formed so as to cover a side surface of the semiconductor chip;
a second insulating layer formed on the circuit forming surface of the semiconductor chip and the first insulating layer so as to expose an end portion of the interconnection terminal and cover the other portions except the end portion, the second insulating layer having a first surface facing the circuit forming surface of the semiconductor chip and the first insulating layer and a second surface opposite to the first surface; and
a wiring pattern formed on the second surface of the second insulating layer and electrically connected with the end portion of the interconnection terminal.

8. The semiconductor device of claim 7, further comprising:
an external connection terminal formed on the wiring pattern,
wherein the external connection terminal is formed at a portion where the external connection terminal overlaps the first insulating layer when viewed from above.

9. The semiconductor device of claim 7, wherein the first insulating layer and the second insulating layer are formed of the same material.

10. The semiconductor device of claim 7, wherein the first insulating layer is formed so as to cover the side surface and a rear surface of the semiconductor chip.
